(19) United States
(12) Patent Application Publication
(10) Pub. No.: US 2023/0094863 A1
(43) Pub. Date: Mar. 30, 2023

(54) A POWER CONVERTER HAVING MULTIPLE MAIN SWITCHES IN SERIES AND A POWER CONVERSION METHOD

(71) Applicant: SIGNIFY HOLDING B.V., EINDHOVEN (NL)

(72) Inventors: Jie FU, SHANGHAI (CN); Liang SHI, SHANGHAI (CN); Shan WANG, SHANGHAI (CN); Gang WANG, SHANGHAI (CN)

(21) Appl. No.: 17/622,596

(22) PCT Filed: Jun. 30, 2020
(86) PCT No.: PCT/EP2020/068401

§ 371 Date: Dec. 23, 2021

(30) Foreign Application Priority Data
Jul. 4, 2019 (CN) PCT/CN2019/094655
Aug. 27, 2019 (EP) 19193720.0

(51) Int. Cl. H02M 3/158; H02M 1/088; H02M 3/155; H03K 17/687; H02M 7/217

(52) U.S. Cl. CPC H02M 3/158; H02M 1/088; H02M 3/1557; H03K 17/6871; H02M 7/217

(57) ABSTRACT

A power converter comprises a switch arrangement for controlling a path of current flow through an energy storage element and power commutation thereof so as to provide an output. The switch arrangement comprises at least first and second MOSFETs connected in series and a controlling circuit for determining how the first and second MOSFETs are switched. The timing of operation of the switching arrangement is used to control the output of the power converter. An adjusting circuit is used to adjust an electrical parameter of a component of the controlling circuit according to an operating condition of the power converter, thereby to control an efficiency of the power converter under different operating conditions.

### FIELD OF THE INVENTION

This invention relates to power converters, in particular switch mode power converters in which the main converter switch is formed as at least two switches in series.

### BACKGROUND OF THE INVENTION

High voltage application (such as 347V-480V AC) is always a challenge for the power supply design. For such high power drivers, a bridge circuit is normally used with high voltage components such as insulated gate bipolar transistors (IGBTs) or silicon carbide (SiC) devices.

However, for some low power applications, such as for a standby power supply, such technology and components are too expensive to use. A regular flyback structure is then desired. In such circuits, the high voltage switches become the key elements to cope with the high voltages while keeping a low cost.

For standby power supply applications, the system loss during a standby mode is critical. For high voltage applications, it is difficult to achieve the desired low power loss as a result of the high switching losses, resulting from the high voltage stress on the main switch of the power converter.

It has been proposed to use a cascade FET structure in which the main power switch of the converter is implemented as two series-connected transistors. This shares the operating voltage across the two devices. However, this structure still has problems meeting the desired standby power requirements.

US20100309689A1 discloses a converter circuit with two series swtiches, and the capacitance at the base of the upper switch can be adjusted to divert the base current provided to the upper switch.

US20160172961A1 discloses a converter circuit with two series MOSFETs.

US20160172961A1 discloses changing a switching speed of a switching element based on a power supply current.

### SUMMARY OF THE INVENTION

It has been found that the circuit efficiency of a cascaded MOSFET converter varies with different load and input voltage conditions.

There is therefore still a need for a low cost power converter circuit which is able to operate at high voltages but with low power consumption, particularly when operating as standby power supply circuit.

The invention is defined by the claims.

It is a concept of the invention to provide a power converter with a switching arrangement in the form of at least first and second MOSFETs connected in series. The way in which an input voltage is divided between the first and second MOSFETs when they are turned on is controlled by a controlling circuit, and by adjusting an electrical parameter of a component of the controlling circuit according to an operating condition of the power converter. This controls an efficiency of the power converter under different operating conditions. More specifically, the component could be a voltage threshold element that determines how much voltage the lower switch undertakes; and/or a capacitance that applies charge to the upper switch to turn it on.

According to examples in accordance with an aspect of the invention, there is provided a power converter comprising:

an input for receiving an input voltage;

an energy storage element connected to the input;

a switch arrangement for controlling a path of current flow through the energy storage element and power commutation thereof so as to provide an output, wherein the switch arrangement comprises at least first and second transistors connected in series and a controlling circuit for determining how the first and second transistors are switched, wherein the timing of operation of the switching arrangement is used to control the output of the power converter; and

an output coupled to the energy storage element,

wherein the power converter further comprises an adjusting circuit adapted to adjust an electrical parameter of a component of the controlling circuit according to an operating condition of the power converter, thereby to control an efficiency of the power converter under different operating conditions.

This power converter uses a series connection of transistors, such as MOSFETs to share the input voltage. In this way, a high voltage circuit can make use of lower voltage components. In particular, the two MOSFETs are formed as a cascade circuit and a controlling circuit influences how the MOSFETs are switched on/off. The two MOSFETs are intended to switch on and off synchronously, so they function as a single switch.

A problem with such cascade circuits generally is the large switching loss resulting from switching of high voltages. This impacts on the efficiency of the power converter, which is particularly important for low power circuits.

It has been recognized by the inventors that the efficiency of the circuit is a function of the operating condition of the circuit (such as the output power or input voltage level). By adjusting an electrical parameter of a component of the controlling circuit, according to an operating condition of the power converter, an efficiency of the power converter can be controlled under different operating conditions. Thus, the power converter can be operated in the most power efficient way for different operating conditions.

In a first case, the controlling circuit comprises a voltage threshold element for setting a maximum voltage across the second transistor, said voltage threshold element comprises a first voltage threshold element which is a Zener diode circuit and the electrical parameter which is adjusted comprises the threshold level of the Zener diode circuit, thereby the adjusting circuit being adapted to adjust the threshold level of the Zener diode circuit according to the operating condition of the power converter.

The threshold level determines (in combination with a second threshold element) how a voltage is divided between the first and second transistors. By adjusting this division, the efficiency can be improved for different operating conditions.

The voltage threshold element coupled to the drain of the second MOSFET for clamping the voltage across the second MOSFET.

The voltage threshold element clamps the maximum voltage on the drain of the second MOSFET (with respect to ground), thereby determining the maximum voltage across the second MOSFET, and determines the voltage division between the first and second

MOSFETs, whereas the capacitive circuit determines the charge stored for controlling the switching of the first MOSFET (in response to switching of the second MOSFET).

In an example to implement the first case, the adjusting circuit comprises a (second) memory adapted to store a second corresponding relationship between a desired threshold level and each of the operating conditions.

In this case, the Zener diode circuit may comprise a series chain of Zener diodes, wherein the Zener diodes of a sub-set are each associated with a shorting switch, wherein the adjusting circuit is adapted to control the shorting switches. A shorting switch may be in parallel with an individual Zener diode, or a set of the Zener diodes.

This provides a simple way to perform a stepwise threshold voltage level adjustment, with only static components. The sub-set may be all Zener diodes apart from one, which is always in the circuit.

Moreover, the adjustable Zener diode circuit may be considered to be a first voltage threshold element. There may be a second, fixed threshold, Zener diode between the drain of the second MOSFET and the first voltage threshold element, which Zener diode may be considered to be a second voltage threshold element.

The power converter for example comprises a controller for providing a control signal to control the switching of the second transistor.

The second transistor is controlled by a controller (for example to make the power converter deliver a desired output voltage), and the first transistor follows the same switching cycle. Thus, only one control signal is generated for controlling the switching of the first and second transistors.

The energy storage element for example comprises an inductor.

In a second case addtionally or alternative to the first case, the controlling circuit may comprise a capacitive circuit for storing a charge for application to the gate of the first transistor to turn on the first transistor. And the electrical parameter which is adjusted comprises the capacitance of the capacitive circuit. The adjusting circuit is adapted to adjust the capacitance of the capacitive circuit according to the operating condition of the power converter.

To implement this, the adjusting circuit comprises a first memory adapted to store a first corresponding relationship between a desired capacitance and each of the operating conditions.

If the capacitance is too low, there may be insufficient charge to turn on the first MOSFET. If the capacitance is too high, a reduced efficiency results. By dynamically controlling the capacitance, the efficiency is kept as high as possible while ensuring correct switching within the switch arrangement.

The capacitive circuit may then comprise a capacitor bank and a switching circuit for configuring the capacitors of the capacitor bank, wherein the adjusting circuit is adapted to control the switching circuit.

This provides a simple way to perform a stepwise capacitance adjustment, with only static components. The capacitive circuit for example comprises a set of parallel capacitors, wherein the capacitors of a sub-set (e.g. all capacitors apart from one, which is always in the circuit) each have an associated series isolating switch, wherein the adjusting circuit is adapted to control the isolating switches.

In one implementation, MOSFETs are used as the transistors.

The operating condition may comprise the output power of the power converter. The operating condition may additionally or alternatively comprise the level of the input voltage.

The converter typically further comprises a rectifier for receiving a mains input and generating the input voltage as a rectified mains voltage. The power converter is thus a high voltage circuit, but it may be for a low power output. Such circuits generally suffer from efficiency problems.

The power converter for example comprises:

a flyback converter, wherein the energy storage element is a primary side winding of an output transformer, and the load connects to a secondary side winding of the output transformer; or

a boost converter; or

a SEPIC converter.

The power converter may comprise a standby power supply circuit.

The invention also provides a power conversion method comprising: receiving an input voltage;

controlling the timing of operation of a switch arrangement to control a path of current flow through an energy storage element and to control power commutation thereof so as to provide an output, wherein the switch arrangement comprises at least first and second MOSFETs connected in series and a controlling circuit for determining how the input voltage is divided between the first and second MOSFETs when they are turned on;

coupling an output from the energy storage element; and

adjusting an electrical parameter of a component of the controlling circuit according to an operating condition of the power converter, thereby to control an efficiency of the power converter under different operating conditions.

These and other aspects of the invention will be apparent from and elucidated with reference to the embodiment(s) described hereinafter.

### BRIEF DESCRIPTION OF THE DRAWINGS

For a better understanding of the invention, and to show more clearly how it may be carried into effect, reference will now be made, by way of example only, to the accompanying drawings, in which:

FIG. 1 shows a known example of a cascade FET structure, based on flyback converter topology;

FIG. 2 shows a first example of a power converter in accordance with the invention. It is shown as a modification to the circuit of FIG. 1;

FIGS. 3A to 3C show portions of an efficiency table showing the efficiency of a capacitance value for different possible input voltages, primary side current and output power;

FIG. 4 shows an implementation of the approach of FIG. 2 for a boost converter;

FIG. 5 shows another example in which the electrical parameter which is adjusted comprises the threshold level of a Zener diode circuit;

FIG. 6 shows an alternative implementation of the Zener diode bank;

FIG. 7 shows the circuit efficiency versus different load, line voltage and Zener diode voltage;

FIGS. 8A and 8B show another circuit example inside a single-ended primary-inductor converter (SEPIC) topology; and

FIG. 9 shows a power conversion method.

### DETAILED DESCRIPTION OF THE EMBODIMENTS

The invention will be described with reference to the Figures.

It should be understood that the detailed description and specific examples, while indicating exemplary embodiments of the apparatus, systems and methods, are intended for purposes of illustration only and are not intended to limit the scope of the invention. These and other features, aspects, and advantages of the apparatus, systems and methods of the present invention will become better understood from the following description, appended claims, and accompanying drawings. It should be understood that the Figures are merely schematic and are not drawn to scale. It should also be understood that the same reference numerals are used throughout the Figures to indicate the same or similar parts.

The invention provides a power converter comprises a switch arrangement for controlling a path of current flow through an energy storage element and power commutation thereof so as to provide an output. The switch arrangement comprises at least first and second MOSFETs connected in series and a controlling circuit for determining how the first and second MOSFETs are switched (and how the input voltage is divided between the first and second MOSFETs when they are turned on). The timing of operation of the switching arrangement is used to control the output of the power converter. An adjusting circuit is used to adjust an electrical parameter of a component of the controlling circuit according to an operating condition of the power converter, thereby to control an efficiency of the power converter under different operating conditions.

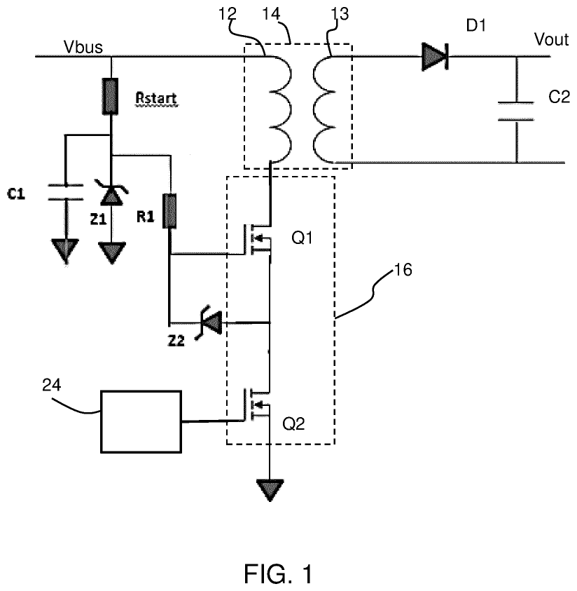

FIG. 1 shows a known example of a cascade FET structure, based on flyback converter topology.

The circuit comprises an input for receiving an input voltage Vbus and an energy storage element 12 connected to the input, in this example the primary winding of an output transformer 14. The secondary winding 13 of the transformer 14 connects to the output through a diode D1 and delivers an output voltage Vbus. The output voltage is smoothed by capacitor C2.

A switch arrangement 16 is for controlling a path of current flow through the energy storage element 12 and power commutation thereof so as to provide an output.

The switch arrangement comprises first and second MOSFETs Q1, Q2 connected in series.

In a turn off procedure, a controller IC 24 begins to turn off the second MOSFET Q2, its drain voltage increases, which is the source voltage of the first MOSFET Q. The first MOSFET has a reducing gate-source voltage and thus also begins to turn off. A driving capacitor C1 is used to store energy during the time period that the second MOSFET Q2 is turned off. In the turn on procedure, when Q2 is turned on by the controller IC 24, the driving capacitor C1 discharges energy to the first MOSFET Q1 and triggers the first MOSFET Q1. Thus, only the second MOSFET Q2 is controlled by the controller IC 24 of the converter. The two MOSFETs are intended to switch on and off synchronously, so they function as a single switch.

A start up circuit comprises start up resistor Rstart and base resistor R1. They are in series between the input Vbus and the base of the first MOSFET Q1. A Zener diode Z1 provides level control for the base voltage of the first MOSFET Q1. It connects from the junction between the resistors Rstart and R1 to ground. The driving capacitor C1 is in parallel with the Zener diode D1.

A second Zener diode Z2 plus the diode Z1 provides level control of the drain voltage of the second MOSFET Q2. The second Zener diode Z2 connects between the base of the first MOSFET Q1 and the drain of the second MOSFET Q2.

The Zener diodes and driving capacitor C1 may together be considered to implement a controlling circuit, in that they determine the switching behavior of the two MOSFETs. These Zener diodes together determine how the input voltage is divided between the two MOSFETs. The driving capacitor C1 determines how the MOSFET Q1 is driven.

If the driving capacitor C1 is too small, there may not be enough energy to turn on the first MOSFET Q1 and this will lower the efficiency. However, if the driving capacitor C1 is too large, it functions as a snubber capacitor in parallel with the second MOSFET Q2 and generates too much loss on Q2 and hence lowers the efficiency.

It would be desirable to dynamically change the controlling circuit, and thereby maximize the efficiency according to the load and input voltage variation.

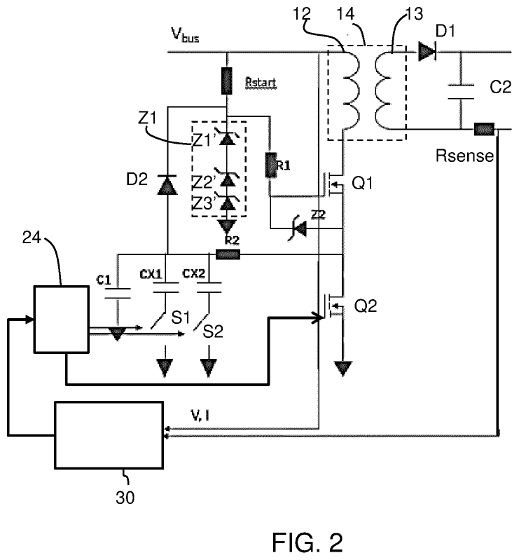

FIG. 2 shows a first example of a power converter in accordance with the invention. It is shown as a modification to the circuit of FIG. 1. It is based on dynamically changing the capacitance of the controlling circuit (i.e. the capacitance of the driving capacitor C1).

As in FIG. 1, the circuit comprises an input for receiving an input voltage Vbus and an energy storage element 12 connected to the input, again the primary winding of an output transformer 14.

A switch arrangement 16 of first and second MOSFETs Q1, Q2 connected in series again controls a path of current flow through the energy storage element 12 and power commutation thereof so as to provide an output.

The start up circuit again comprises start up resistor Rstart and base resistor R1 in series between the input Vbus and the base of the first MOSFET Q1.

The driving capacitor C1 is replaced by a switchable capacitor bank C1, CX1, CX2 with switches S1, S2 and a diode D2 which means current can only flow from the capacitor bank to the junction between the start up resistor Rstart and base resistor R1.

Each switch S1, S2 is in series with a respective one of the capacitors of the capacitor bank, thereby either connecting the capacitor as part of a parallel capacitor circuit, or isolating the capacitor from the capacitor bank. As shown, one capacitor of the parallel capacitor bank C1 defines a minimum capacitance and is always in circuit, and hence does not have a series switch.

The purpose of the capacitor bank is to store the charge for application to the gate of the first MOSFET Q1 to turn on the first MOSFET. The Zener diode Z1 sets the maximum voltage to which the capacitive circuit is charged.

The Zener diode Z1 of FIG. 1 is represented as a series of Zener diodes from the junction between the resistors Rstart and R1 and ground.

A charging resistor R2 is provided between the drain of the second MOSFET Q2 and the capacitor bank. Diode D2 means that the capacitor bank C1 cannot be charged from Vbus so it is charged through the charging resistor R2.

A second Zener diode Z2 between the base of the first MOSFET Q1 and the drain of the second MOSFET and again provides level control of the drain voltage of the second MOSFET Q2. In particular, the second Zener diode Z2 functions as a threshold element for clamping the voltage across the second MOSFET Q2 relative to the base of the first MOSFET Q1, which in turn is determined by the first Zener diode Z1. Thus, the two Zener diodes Z1, Z2 define the operating voltages of the two MOSFETs.

The Zener diodes Z1, Z2 thus determine the voltage division between the first and second MOSFETs, whereas the capacitor C1 in FIG. 1 and hence the capacitor bank in FIG. 2 determine the charge stored for controlling the switching of the first MOSFET Q1, in response to switching of the second MOSFET Q2.

In the circuit of FIG. 2, the capacitance of the capacitor bank can be adjusted. This is one example of the more general concept of adjusting an electrical parameter of a component of the controlling circuit.

The adjustment is made according to an operating condition of the power converter, thereby to control an efficiency of the power converter under different operating conditions.

For this purpose, the circuit comprises a monitoring circuit 30 which receives a measure of the output voltage V and the primary side current I. This information is provided to the controller 24 of the power converter, and the controller then sets the configuration of the switches S1, S2 of the switchable capacitor bank as well as controlling the second MOSFET Q2 (in the same known manner as in FIG. 1), as shown. The controller 24 thus now additionally functions as an adjusting circuit for adjusting the controlling circuit, e.g. for adjusting a capacitance in the example of FIG. 2.

By using a series connection of MOSFETs, a high voltage circuit can make use of lower voltage components. The controlling circuit influences how the MOSFETs share the input voltage level.

By adjusting an electrical parameter of a component of the controlling circuit (the capacitance of the capacitor bank in this example), according to an operating condition of the power converter, an efficiency of the power converter can be controlled under different operating conditions.

In order to determine the desired capacitance to be implemented by the capacitor bank, a relationship may be stored between the capacitance and the load and input voltage.

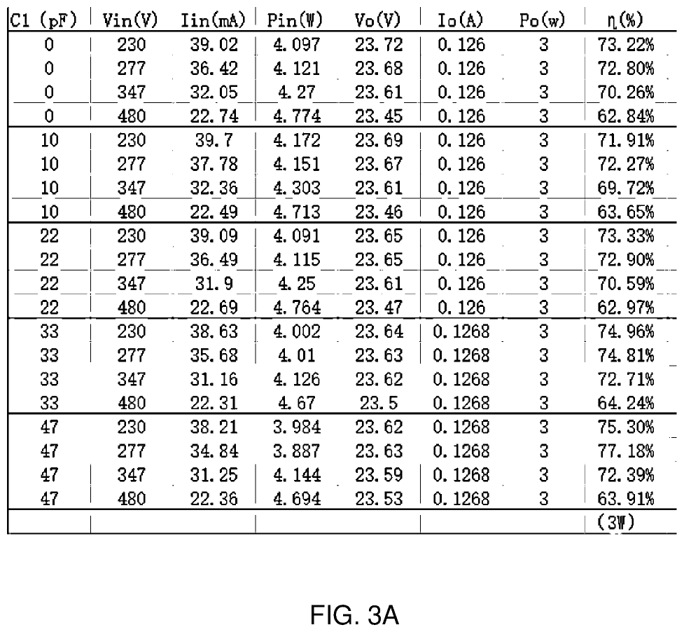

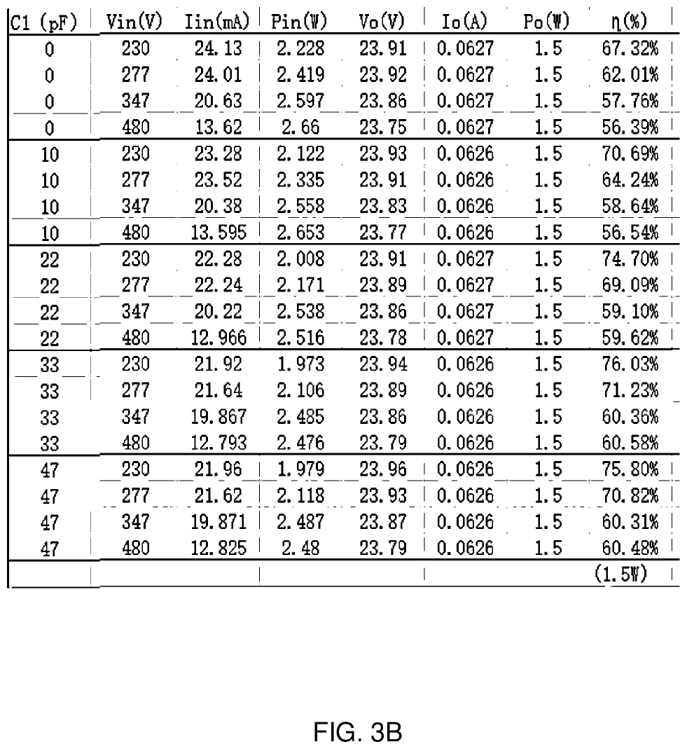

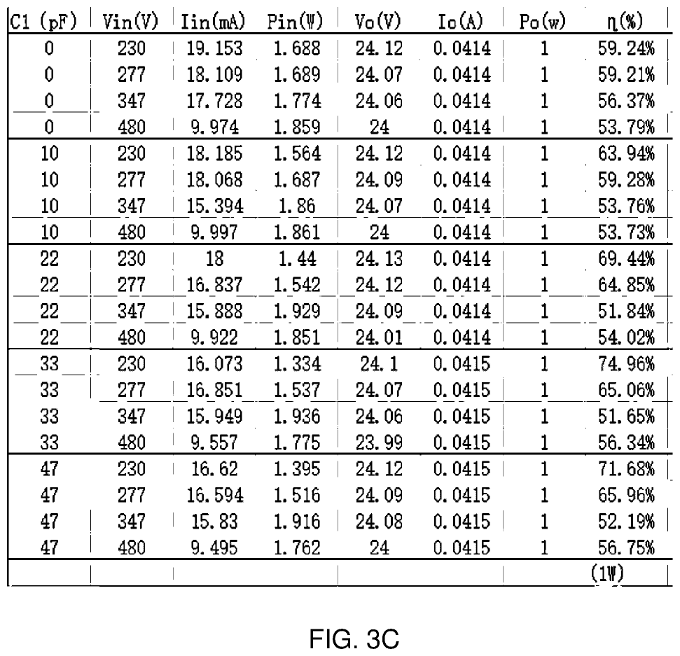

FIG. 3A shows an example of a portion of an efficiency table for a power of 3 W. It shows possible values of C1 (between 0 and 47 pF) for possible input voltages Vin (from 230V to 480V), and for different primary side currents tin (from 22 mA to 39 mA). The corresponding input power Pin is shown (ranging from about 4.0 W to about 4.7 W). The converter is regulated to deliver a fixed output voltage of approximately 24 V and hence a current of approximately 0.13 A to deliver the 3 W output power.

The resulting efficiency η is shown in the last column. A first rule can be identified: at 3 W output, C1 of 33 pF is optimum for the input voltage of 347V and 480V; while C1 of 44 pF is optimum for the input voltage of 230 and 277V.

The operating conditions are selected to optimize the efficiency. For example, an efficiency of 77% is possible.

FIG. 3B shows an example of a portion of the efficiency table for a power of 1.5 W. It shows the same parameters as FIG. 3A. An efficiency of 76% is possible. A second rule can be seen: at 1.5 W output, C1 of 33 pF is optimum for all input voltages.

FIG. 3C shows an example of a portion of the efficiency table for a power of 1.0 W. It shows the same parameters as FIG. 3A. An efficiency of 75% is possible. A third rule can be seen: at 1.0 W, C1 of 0 pF is optimum for the input voltage of 347V; C1 of 33 pF is optimum for the input voltage of 230V; while C1 of 44 pF is optimum for the input voltage of 277 and 480V.

Thus, the highest efficiency with different input voltage and load (output power) conditions determines the desired value of the capacitance of the capacitor bank. Various operating conditions are defined by the tables, including the output power of the power converter, the level of the input voltage, the level of the input current, and the input power.

From the efficiency table of FIGS. 3A to 3C, the above first, second, and third rules are for example stored in a first memory forming part of the controller 24, i.e. forming part of the adjusting circuit. By dynamically finding the optimum capacitance corresponding to detected different load and input voltage, the efficiency is kept as high as possible while ensuring correct switching within the switch arrangement.

FIGS. 3A to 3C show a table suitable for a bank of three capacitors, one fixed and two which may selectively added to the circuit, making four possible capacitance values. Of course, there may be more capacitors than three in the bank.

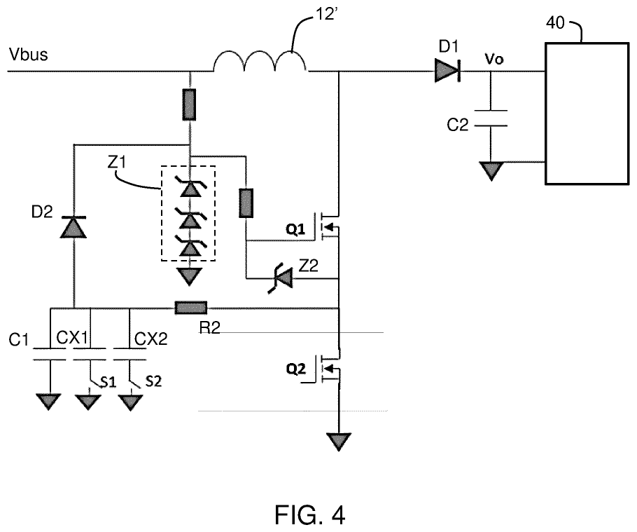

FIG. 4 shows an implementation of the approach of FIG. 2 for a boost converter. The circuit is the same, but the energy storage element is an inductor 12′ which is not part of a transformer. It connects directly to the output. The output load is shown as 40.

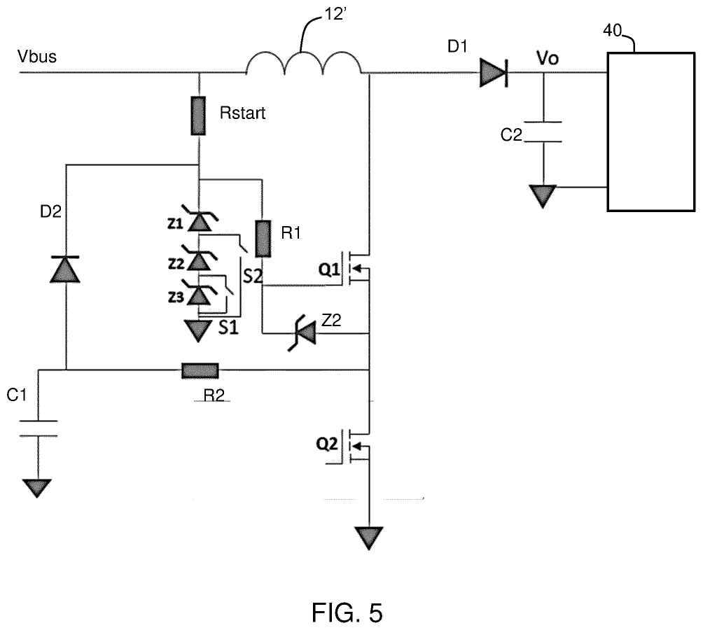

FIG. 5 shows another example in which the electrical parameter which is adjusted comprises the threshold level of the Zener diode circuit which implements Zener diode Z1.

The circuit corresponds to FIG. 4 and hence is a boost converter implementation. However, the capacitor bank is replaced with the single drive capacitor C1 (as in FIG. 1). The Zener diode Z1 is implemented as a series connection of a set of Zener diodes Z1′, Z2′, Z3′ forming a Zener diode bank.

A set of shorting switches S1, S2 enable a selected combination of the Zener diodes to be in series. In this example, switch S1 shorts the bottom Zener diode, and switch S2 shorts the bottom two Zener diodes. If switch S2 is closed, only Z1′ is in the circuit. If switch S1 is closed, Z1′ and Z2′ are in the circuit. If both switches are open, each of the Zener diodes are in the circuit.

Of course, other switch arrangements are possible. For example if the two lower Zener diodes each have a unique parallel switch then a combination of Z1′ and Z3′ is possible. This only provides an additional setting (compared to Z1′ and Z2′) if the Zener diodes are not identical. There may be more than 3 Zener diodes in the bank.

The adjusting circuit then provides a mapping between the Zener diode threshold level which is desired and the operating parameters, in the same way as shown in FIGS. 3A to 3C. For example the adjusting circuit then has a (second) memory adapted to store a (second) corresponding relationship between a desired threshold level and each of the operating conditions.

The threshold level implemented by the Zener diode bank determines how a voltage is divided between the first and second MOSFETs. By adjusting this division, the efficiency can be improved for different operating conditions.

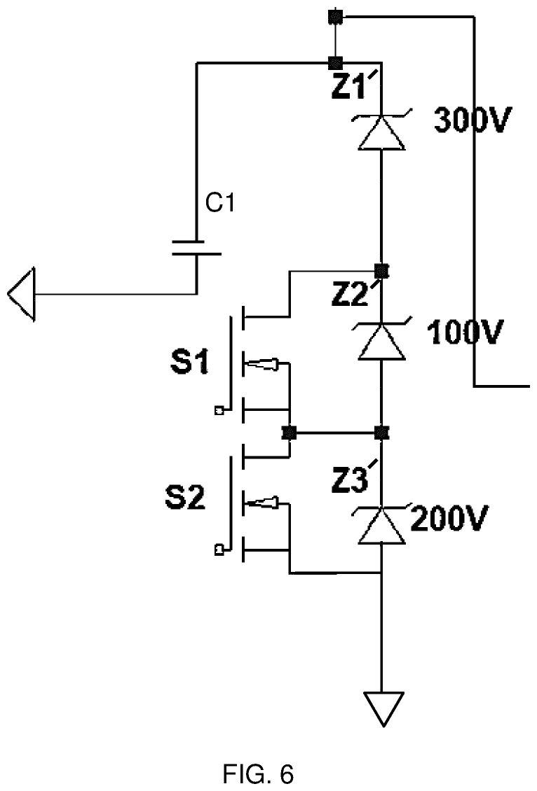

FIG. 6 shows an alternative implementation of the Zener diode bank in which the second and third Zener diodes Z2′ and Z3′ have a parallel switch S1, S2 (as also mentioned above). The threshold voltages of the three Zener diodes are all different (100V, 200V and 300V). The combined threshold voltage may thus be 300V, 400V, 500V or 600V.

By way of example, a simple control table may be used, based only on the general output power level, as shown below:

| Po | S1 | S2 |
|---|---|---|
| 0-0.5 W | on | off |
| 0.5-1.5 W | on | off |
| 1.5 W-3 W | on | on |

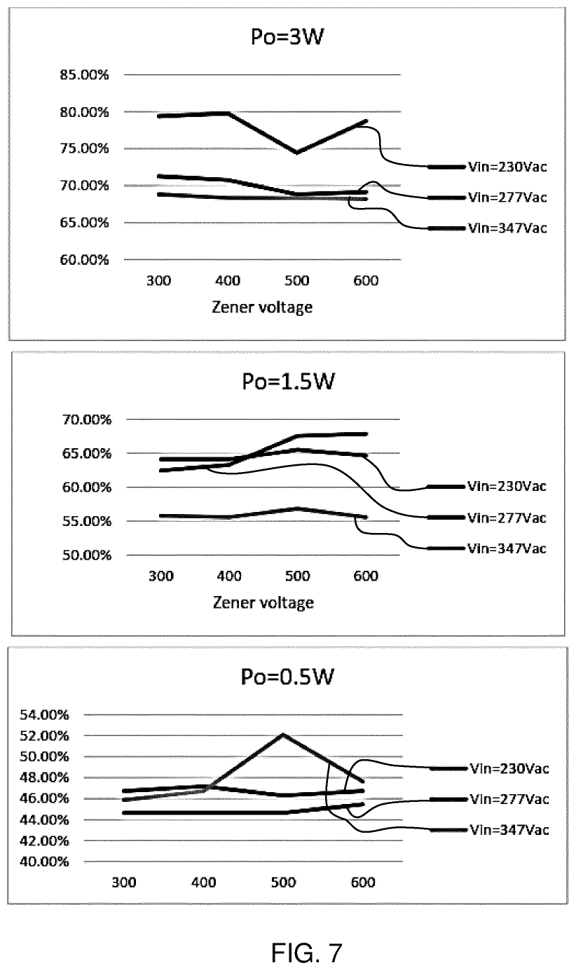

FIG. 7 shows the circuit efficiency versus different load, line voltage and Zener diode voltage. It shows graphically information corresponding to the tables of FIGS. 3A to 3C. It is used to explain the simple control scheme shown by the table above.

The top plot show a load of around 3 W. The sum of the Zener voltages is preferred to be 300V to achieve the highest average efficiency (the y-axis) under different line voltages, so S1 and S2 are turned on to short out Z2′ and Z3′.

The middle plot shows a load of around 1.5 W. The sum of the Zener voltages is preferred to be 500V to achieve highest average efficiency under different line voltages, so S1 is on and S2 is off.

The bottom plot shows a load of around 0.5 W. The sum of the Zener voltages is again preferred to be 500V to achieve highest average efficiency under different line voltages, so S1 is on and S2 is off.

The table above can be stored in the controller 24 and used to control the switches at different conditions to achieve high efficiency.

As explained in connection with FIGS. 3A to 3C, the line voltage may also be measured and the efficiency can be monitored in real-time so the switch setting can be controlled in a more intelligent manner to achieve the highest efficiency.

Thus, the same operating parameters may be monitored to control the adjustment of capacitance or Zener diode threshold. Indeed, both approaches may also be combined.

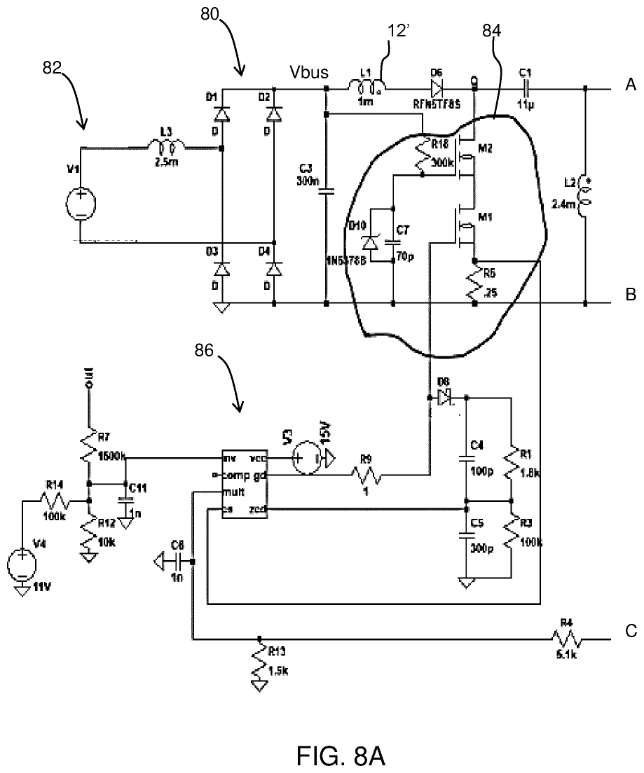

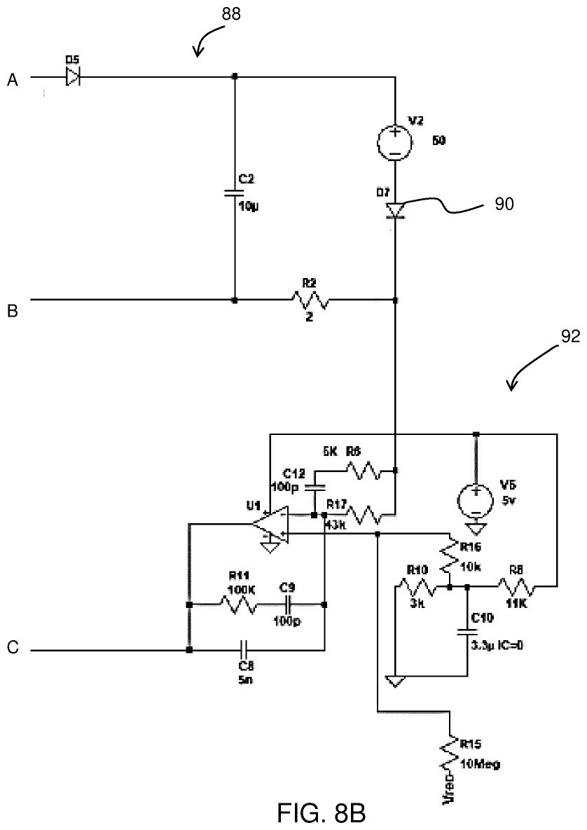

FIG. 8 shows another example inside a single-ended primary-inductor converter (SEPIC) topology which may be modified to implement the invention. FIG. 8 is divided into two parts, shown in FIG. 8A and FIG. 8B.

For completeness, it shows a converter having:

a rectifier 80 for receiving a mains input 82 and generating the input voltage as a rectified mains voltage;

the energy storage element 1′;

the switch arrangement and controlling circuit as described above, shown generally at 84;

a switch controller 86;

an output circuit 88;

the output LED load 90; and

a feedback circuit 92 for providing feedback information to the switch controller 86.

A single Zener diode D10 is shown in the circuit 84 to represent the Zener diode bank. By adjusting the threshold of the Zener diode D10, the efficiency is controlled.

The table below shows a simulation of the effect of varying the threshold voltage of Zener diode D10:

| | 25 W with 50 V, 0.5 A | 60 W with 120 V, 0.5 A |
|---|---|---|
| D10 voltage | Efficiency | Efficiency |
| 100 V | 82.9% | 81.3% |
| 200 V | 83% | 84.5% |
| 300 V | 80.2% | 88.5% |

The circuit of FIG. 8 may alternatively or additionally be modified to provided adjustable capacitance (of capacitor C7) in the manner explained above.

The invention may be applied to different converter topologies, including the flyback example given above, wherein the energy storage element is a primary side winding of an output transformer, and the load connects to a secondary side winding of the output transformer. Boost converter examples are also given above as well as a SEPIC converter example. Another example is a Cuk converter.

The power converter may comprise a standby power supply circuit.

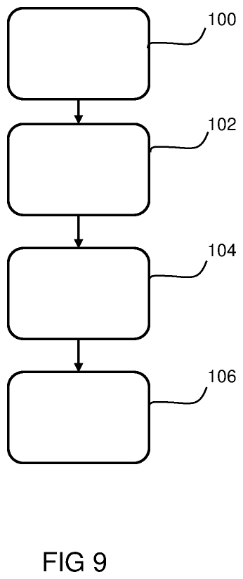

The various circuit options each implement a power conversion method as shown in FIG. 9, comprising:

in step 100, receiving an input voltage;

in step 102, controlling the timing of operation of a switch arrangement to control a path of current flow through an energy storage element and to control power commutation thereof so as to provide an output, wherein the switch arrangement comprises at least first and second MOSFETs connected in series and a controlling circuit for determining how the input voltage is divided between the first and second MOSFETs when they are turned on;

in step 104, coupling an output from the energy storage element; and

in step 106, adjusting an electrical parameter of a component of the controlling circuit according to an operating condition of the power converter, thereby to control an efficiency of the power converter under different operating conditions.

Variations to the disclosed embodiments can be understood and effected by those skilled in the art in practicing the claimed invention, from a study of the drawings, the disclosure and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. If the term “adapted to” is used in the claims or description, it is noted the term “adapted to” is intended to be equivalent to the term “configured to”. Any reference signs in the claims should not be construed as limiting the scope.

1. A power converter comprising:
an input for receiving an input voltage;
an energy storage element connected to the input;
a switch arrangement for controlling a path of current flow through the energy storage element and power commutation thereof so as to provide an output, wherein the switch arrangement comprises at least first and second transistors connected in series and a controlling circuit for determining how the first and second transistors are switched, wherein the timing of operation of the switching arrangement is used to control the output of the power converter; and
an output coupled to the energy storage element,
wherein the power converter further comprises an adjusting circuit adapted to adjust an electrical parameter of a component of the controlling circuit according to an operating condition of the power converter, thereby to control an efficiency of the power converter under different operating conditions,
wherein:
the controlling circuit comprises a voltage threshold element for setting a maximum voltage across the second transistor, said voltage threshold element comprises a first voltage threshold element which is a Zener diode circuit and the electrical parameter which is adjusted comprises the threshold level of the Zener diode circuit, thereby the adjusting circuit being adapted to adjust the threshold level of the Zener diode circuit according to the operating condition of the power converter, and/or
the controlling circuit comprises a capacitive circuit for storing a charge for application to a control terminal of the first transistor to turn on the first transistor, the electrical parameter which is adjusted comprises the capacitance of the capacitive circuit, thereby the adjusting circuit being adapted to adjust the capacitance of the capacitive circuit according to the operating condition of the power converter, wherein the capacitive circuit comprises a capacitor bank comprising a driving capacitor and another capacitor, a switching circuit for configuring the capacitors of the capacitor bank wherein the switching circuit is adapted to:
switch in the other capacitor in the capacitor bank so that both the driving capacitor and the another capacitor to store enemy and apply the stored energy to turn on the first transistor or
isolate the other capacitor from the capacitor bank so that the driving capacitor, not the another capacitor, to store energy and apply the stored energy to turn on the first transistor.

2. The power converter as claimed in claim 1, comprising a controller for providing a control signal to control the switching of the second transistor.

3. The power converter as claimed in claim 1, wherein the energy storage element comprises an inductor.

4. The power converter as claimed in claim 1, wherein the transistors are MOSFETs, the first voltage threshold element is coupled to the drain of the second MOSFET and the ground for clamping the voltage across the second MOSFET.

5. The power converter as claimed in claim 4, wherein the controlling circuit further comprises a second voltage threshold element coupled to the drain of the second MOSFET for clamping the voltage across the second MOSFET.

6. The power converter as claimed in claim 1, wherein the adjusting circuit comprises a first memory adapted to store a first corresponding relationship between a desired capacitance of the capacitance of the capacitive circuit and each of the operating conditions.

7. the power converter as claimed in claim 1, wherein the capacitive circuit comprises a capacitor bank and a switching circuit for configuring the capacitors of the capacitor bank, wherein the adjusting circuit is adapted to control the switching circuit.

8. The power converter as claimed in claim 1, wherein the adjusting circuit comprises a second memory adapted to store a second corresponding relationship between a desired threshold level of the Zener diode circuit and each of the operating conditions.

9. The power converter as claimed in claim 1, wherein the Zener diode circuit comprises a series chain of Zener diodes, wherein the Zener diodes of a sub-set each are associated with a shorting switch, wherein the adjusting circuit is adapted to control the shorting switches.

10. The power converter as claimed claim 1, wherein the operating condition comprises the output power of the power converter.

11. The power converter as claimed in claim 1, wherein the operating condition comprises the level of the input voltage.

12. The power converter as claimed in claim 1,further comprising a rectifier for receiving a mains input and generating the input voltage as a rectified mains voltage.

13. The power converter as claimed in claim 1, comprising:
a flyback converter, wherein the energy storage element is a primary side winding of an output transformer, and the load connects to a secondary side winding of the output transformer; or
a boost converter; or
a SEPIC converter.

14. The power converter as claimed in claim 1, comprising a standby power supply circuit.

15. A power conversion method comprising:
receiving an input voltage;
controlling the timing of operation of a switch arrangement to control a path of current flow through an energy storage element and to control power commutation thereof so as to provide an output, wherein the switch arrangement comprises at least first and second MOSFETs connected in series and a controlling circuit for determining how the first and second MOSFETs are switched;
coupling an output from the energy storage element; and
adjusting an electrical parameter of a component of the controlling circuit according to an operating condition of the power converter, thereby to control an efficiency of the power converter under different operating conditions,
wherein the controlling circuit comprises a voltage threshold element for setting a maximum voltage across the second MOSFET, said voltage threshold element comprises a first voltage threshold element which is a Zener diode circuit and the electrical parameter which is adjusted comprises the threshold level of the Zener diode circuit, thereby the step of adjusting comprising adjusting the threshold level of the Zener diode circuit according to the operating condition of the power converter; and/or
the controlling circuit comprises a capacitive circuit for storing a charge for application to the gate of the first MOSFET to turn on the first MOSFET, the electrical parameter which is adjusted comprises the capacitance of the capacitive circuit, thereby the step of adjusting being adjusting the capacitance of the capacitive circuit according to the operating condition of the power converter wherein the capacitive circuit comprises a capacitor bank comprising a driving capacitor and another capacitor, a switching circuit for configuring the capacitors of the capacitor bank wherein the step of adjusting comprises switching in the another capacitor in the capacitor bank so that both the driving capacitor and the another capacitor to store energy and apply the stored energy to turn on the first transistor or
isolating the another capacitor from the capacitor bank so that the driving capacitor, not the another capacitor, to store energy and apply the stored energy to turn on the first transistor.
